(19) United States
(12) Patent Application Publication
(10) Pub. No.: US 2002/0020913 A1
(43) Pub. Date: Feb. 21, 2002

(54) Method of producing a buffer element to reduce mechanical stresses

(76) Inventors: Wolfgang Knapp, Wettingen (CH); Fabian Zwick, Adliswil (CH)

Correspondence Address: BURNS DOANE SWECKER & MATHIS L L P, POST OFFICE BOX 1404, ALEXANDRIA, VA, 22313-1404, US

(21) Appl. No.: 09/928,487

(22) Filed: Aug. 14, 2001

(30) Foreign Application Priority Data
Aug. 21, 2000 (EP) 00810742.7

(51) Int. Cl. H01L 23/34

(52) U.S. Cl. 257/712

(57) ABSTRACT

In a method of producing a self-supporting buffer element which is intended to reduce mechanical stresses between two materials with different coefficients of thermal expansion and therefore has regions capable of expansion and/or contraction essentially independently of one another, a metal sheet (1) is deformed into a three-dimensional structure (1′, 1″) in such a way that it can be divided into areas which are capable of expansion and/or contraction essentially independently of one another, whereupon the three-dimensional structure (1, 1″) is pressed and worked to form a structured plate (P).

This method can be used to create buffer elements which can be produced easily, are stable and can be handled easily, for applications in particular in semiconductor technology.

### FIELD OF THE INVENTION

The invention relates to the field of power electronics. It concerns a method of producing a buffer element to reduce mechanical stresses between two materials with different coefficients of thermal expansion according to the preamble of patent claim 1 and also to a buffer element according to the preamble of patent claim 14.

### BACKGROUND OF THE INVENTION

Buffer elements of this type are used in high-power semiconductor devices in order to minimize thermally induced mechanical stresses between a semiconductor element and a plate-shaped metal electrode. Mechanical stresses lead to fatigue of the bonding layers between the semiconductor element and the metal electrodes, consequently impair the electrical behavior of the semiconductor device and can lead to its failure.

One response to this in the prior art is therefore to use what are known as presspack modules, in which the semiconductor chip and metal electrodes are pressed against one another by means of external spring elements, without the use of solder layers. This does admittedly create sliding electrical contacts which are not subject to any thermally induced mechanical stresses. However, it is disadvantageous that these contacts have a relatively high thermal resistance, with the result that the functional capability of the device is limited.

It is also known to arrange buffer elements between the semiconductor chip and metal electrodes in order to absorb the mechanical stresses. In order not to impair the functional capability of the semiconductor device, the buffer elements must have good thermal and electrical conductivity.

James Burgess et al., “Solder Fatigue Problems in a Power Package”, IEEE Transactions on components, hybrids and manufacturing technology, vol. chmt-7, no. 4, December 1984, pages 405-410, describes a buffer element of this type, referred to here as “structured copper”. This buffer element of copper comprises a multiplicity of pieces of copper wire arranged in series, which can move independently of one another. If they are used as a link between two materials with different coefficients of thermal expansion, their freedom of movement enables them to absorb mechanical stresses without transferring them to the other elements in the bond.

Homer H. et al., “Structured copper: a pliable high conductance material for bonding to silicon power devices”, IEEE Transactions on components, hybrids and manufacturing technology, vol. chmt-6, no. 4, December 1983, pages 460-466, describes how “structured copper” elements of this type are produced. A thin, coated copper filament, typically with a diameter of a quarter of a millimeter, is wound around two bars arranged at a distance from each other. The coil obtained in this way is pushed into a copper tube, which is drawn through a wire-drawing bench. Subsequently, the tube is pressed together with the coil several times, until a winding density of up to 1600 wires per square centimeter is achieved. To conclude, the tube is cut into disks. A disk comprising loose pieces of copper wire held together by a copper ring is obtained. If the ring is to be removed, the pieces of copper wire must be connected to one another, for example soldered together, at one end.

A “structured copper” element of this type is also described in U.S. Pat. No. 4,385,310.

These buffer elements of structured copper have admittedly proven to be successful. Unfortunately, however, their production is time-consuming and therefore cost-intensive. Moreover, these buffer elements are fragile and difficult to handle on account of the loose pieces of wire.

### SUMMARY OF THE INVENTION

It is therefore the object of the invention to provide a more simple method of producing a buffer element and also a more stable buffer element.

This object is achieved by a method of production with the features of patent claim 1 and a buffer element with the features of patent claim 14.

According to the invention, a metal sheet is initially taken and three-dimensionally deformed to divide it into areas which are capable of expansion and/or contraction essentially independently of one another, and is transformed by subsequent pressing into a buffer element in the form of a structured plate, which consequently has regions capable of expansion and/or contraction essentially independently of one another.

Production is greatly simplified by the choice of a metal sheet instead of copper wires. Three to four simple working steps are sufficient to produce the structured plate.

The buffer element according to the invention is formed at least approximately as one piece and therefore does not have to be held together by external fixing means. It is self-supporting, much more stable and easier to handle than the known “structured copper” elements. A further advantage is that buffer elements with much smaller thicknesses than the known “structured copper” elements composed of small pieces of wire can be produced.

In a preferred first variant of the method, the metal sheet is structured by deep drawing, to then be deformed by lateral and preferably also vertical pressing into an at least approximately plane-parallel structured plate.

In a preferred second variant of the method, the sheet is folded and, in the folded state, wound up into a roll, which is subsequently pressed together in a perpendicular direction in relation to its longitudinal axis. This roll can be cut along its longitudinal axis into disks, which in turn, preferably after vertical pressing, form the desired plate-shaped buffer elements.

Further advantageous variants of the method and advantageous embodiments emerge from the dependent patent claims.

### BRIEF DESCRIPTION OF THE DRAWINGS

The subject-matter of the invention is explained in more detail below on the basis of preferred exemplary embodiments which are represented in the attached drawings, in which:

FIGS. 1a to 1f show production of a buffer element in a first variant of the method according to the invention in several steps and

FIGS. 2a to 2f show the production of the buffer element according to a second variant of the method according to the invention.

### DETAILED DESCRIPTION OF THE INVENTION

In the method according to the invention, a metal sheet 1 is initially taken. This is preferably a copper or aluminum sheet. The sheet preferably has a thickness of from 0.1 mm to 2 mm. It should be soft enough to allow it to be deformed in a simple way without rupturing. The use of a rectangular, in particular square, sheet is preferred.

According to the invention, in a first production step, the sheet 1 is deformed into a three-dimensional structure 1′, 1″, which can be divided into areas which are capable of expansion and/or contraction essentially independently of one another.

In a second step, this three-dimensional structure 1′, 1″ is pressed, to be worked in a subsequent step into a structured plate P with a predetermined thickness.

The buffer element consequently has the form of a structured plate which comprises a pressed-together sheet having a meandering form.

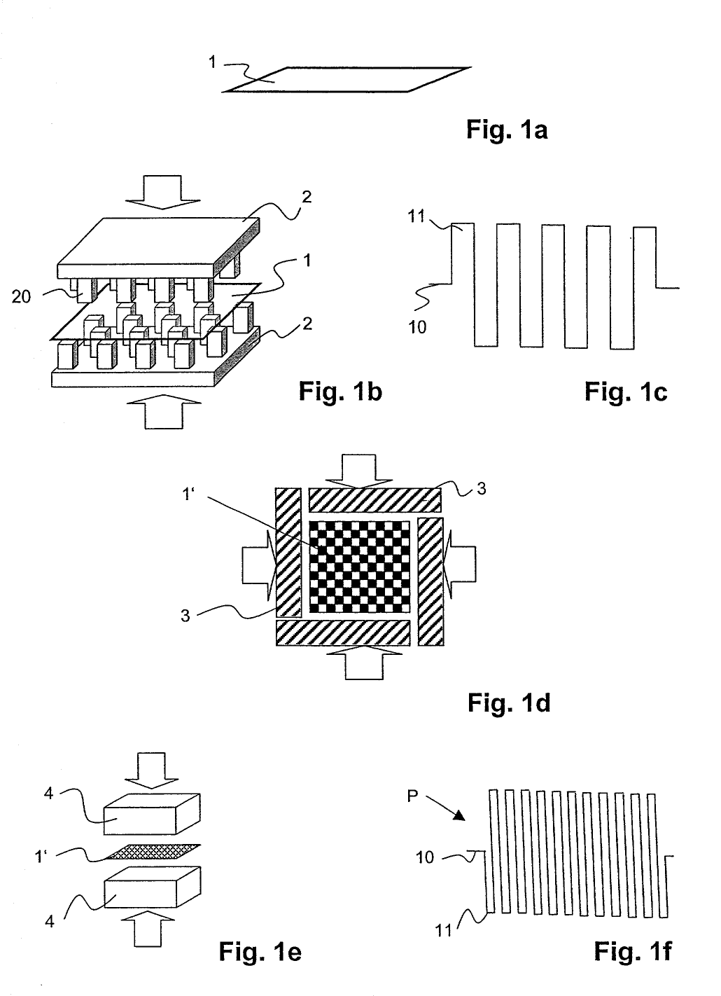

In FIGS. 1a to 1f a first variant of the method of production according to the invention is represented. In FIG. 1a, the sheet 1 described above is represented. In a first production step according to FIG. 1b, the sheet 1 is deep-drawn, in that fingers 11 protruding out of a sheet plane 10 are formed in it by pressing. This takes place for example by means of a die 2, which has correspondingly shaped die strikers 20. In this operation, fingers 11 are preferably formed into the sheet plane 10 by pressing on both sides, for example by dies 2 being pressed simultaneously against each other from both sides.

As represented in FIG. 1c, a three-dimensional structure 1′ which has a meandering cross section is produced. In FIG. 1c, rectangular fingers 11 are represented. The form depends, however, on the type of dies 2 used, which are chosen according to the properties of the buffer element to be achieved. In particular, the fingers 11 may also have rounded surfaces. In this example, the structure 1′ has in plan view a chequered pattern, as can be seen best in FIG. 1d. Here, the black areas illustrate downwardly protruding fingers 11, the white areas upwardly protruding fingers 11. Other forms are possible however.

In the next production step, which is represented in FIG. 1d, the three-dimensional structure 1′ is pressed laterally, parallel to the sheet plane 10. In this operation, first pressing strikers 3 are applied to the structure in the sheet plane from at least two sides, here from four sides. This pressing preferably takes place uniformly from all four sides. It must be ensured here that the structure 1′ cannot deviate excessively in a perpendicular direction in relation to the sheet plane 10. This is preferably prevented by placing the structure 1′ between two counter-plates (not represented here). The structure 1′ is pressed together to a desired density, depending on subsequent use. After pressing, it preferably has a density of from 70 to 99%.

In a final step according to FIG. 1e, the three-dimensional structure 1′ is pressed together vertically, in a perpendicular direction in relation to the sheet plane 10. This takes place by two pressing strikers 4 being applied, one on each side.

This final method step can be carried out at the same time as the lateral pressing. Moreover, the third dies 4 can be used as counter-plates.

In FIG. 1f, the buffer element obtained is represented in cross section. It comprises a plate P which has a meandering cross section, the meander having been pressed together into a dense pack, but nevertheless allowing the limbs of the meander to move largely independently of one another.

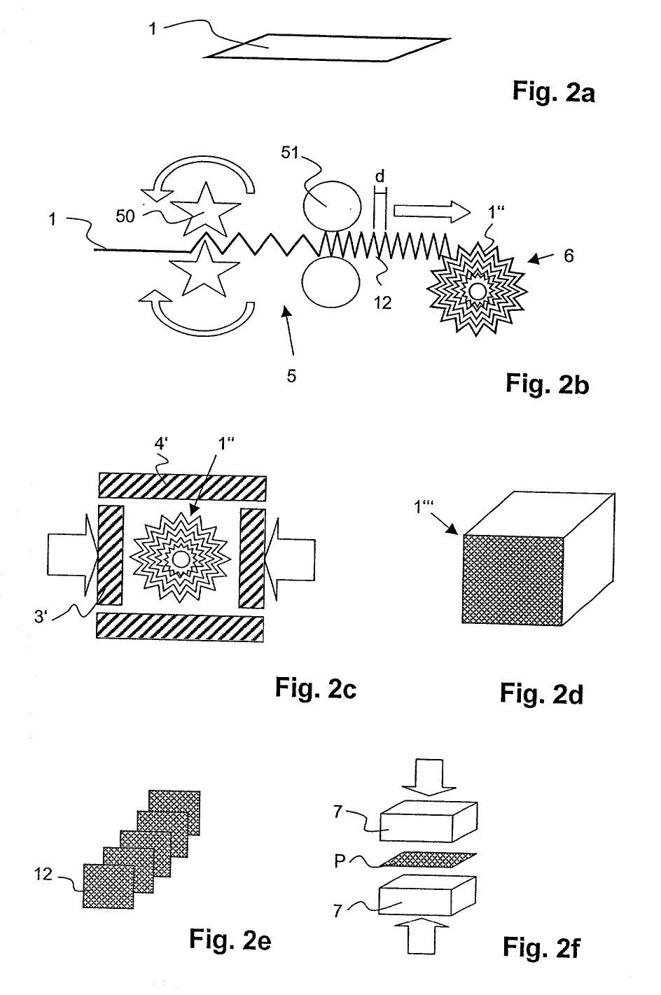

In FIGS. 2a to 2f, a second variant of the method according to the invention is represented. According to FIG. 2a, once again the metal sheet 1 is initially taken as the starting material. In a first method step, it is passed through a folding apparatus 5, only two star-shaped folding rollers 50 and two transporting rollers 51 being schematically represented in FIG. 2b. The sheet 1 is folded between the two folding rollers 50. In the example represented here, the sheet 1 is bent at regular intervals, producing a corrugated sheet 12 with pointed edges. Other forms of folding are also possible however, in particular round edges. In the subsequently arranged transporting rollers 51, the corrugated sheet 12 is brought with a desired point spacing d to a winding device 6. On this winding device 6, the folded starting material is wound up into a structured roll 1″ with a star-shaped cross section. In this operation, it is ensured that the folded structure of the sheet 1 is retained. That is to say, the winding speed and the tension of the feed must be chosen appropriately.

The three-dimensional structure produced in this way in the form of the roll 1″ is pressed together in a next method step according to FIG. 2c in an least approximately perpendicular direction in relation to its longitudinal axis. The structured roll 1″ is preferably pressed into a rectangular, in particular square, cross-sectional form. Pressing strikers 3′ are again used for this purpose. The pressing strikers 3′ are preferably applied simultaneously to the roll 1″, from at least two opposite sides, counter-plates 4′ being present on the other sides.

In FIG. 2d, the pressed-together, now cuboidal roll 1′″ is represented. It has a density which is adapted to the intended use. If used as an intermediate layer between a semiconductor chip and a metal plate in a high-power semiconductor element, the density is preferably 70 to 99%.

In a next method step according to FIG. 2e, the pressed-together roll 1′″ is cut along its longitudinal axis into disks 12.

In a final method step, the disks 12 are preferably pressed together perpendicularly in relation to their disk plane by means of pressing strikers 7, to obtain a surface which is as planar as possible. This pressing can be carried out individually for each disk or jointly for a number of disks, intermediate layers preferably being used in the latter case. This again results in a buffer element in the form of a structured plate P which comprises a one-piece, spirally wound sheet, the spiral having windings which extend in a meandering manner.

The buffer element according to the invention is generally suitable as a connecting element for two materials with different coefficients of thermal expansion. However, a preferred application area is in semiconductor technology.

List of designations

1 metal sheet

1′ three-dimensional structure

1″ structured roll

1′″ pressed-together roll

10 sheet plane

11 fingers

12 corrugated sheet

2 dies

20 die strikers

3 first pressing strikers

3′ pressing strikers

4 second pressing strikers

4′ counter-plates

5 folding apparatus

50 folding rollers

51 transporting rollers

6 winding device

7 third pressing strikers

d point spacing

p structured plate

1. A method of producing a self-supporting buffer element to reduce mechanical stresses between two materials with different coefficients of thermal expansion, the buffer element having regions capable of expansion and/or contraction essentially independently of one another, characterized in that a metal sheet (1) is deformed into a three-dimensional structure (1′, 1″) in such a way that the three-dimensional structure (1′, 1″) can be divided into areas which are capable of expansion and/or contraction essentially independently of one another, and in that the three-dimensional structure (1′, 1″) is pressed and worked to form a structured plate (P).

2. The method as claimed in claim 1, characterized in that a sheet (1) of copper or aluminum is used.

3. The method as claimed in claim 1, characterized in that a sheet (1) with a thickness of from 0.1 mm to 2 mm is used.

4. The method as claimed in claim 1, characterized in that, to form the three-dimensional structure (1″), the sheet (1) is deep-drawn, fingers (10) protruding out of a sheet plane (10) being formed in it by pressing, and in that the three-dimensional structure (1″) is pressed together parallel to the sheet plane (10) and perpendicular to it.

5. The method as claimed in claim 4, characterized in that the fingers (11) are formed by pressing into the sheet (1) on both sides.

6. The method as claimed in claim 4, characterized in that the three-dimensional structure (1′) in the sheet plane (10) is pressed in at least two directions, in particular in four directions.

7. The method as claimed in claim 4, characterized in that the three-dimensional structure (1′) is pressed together parallel to the sheet plane (10) to a density of from 70 to 99%.

8. The method as claimed in claim 4, characterized in that the three-dimensional structure (1′) is compacted perpendicularly to the sheet plane (10) to a degree of from 0 to 30%.

9. The method as claimed in claim 1, characterized in that, to form the three-dimensional structure, the metal plate (1) is folded and wound up into a roll (1″), in that the roll (1″) is pressed together in a perpendicular direction in relation to its longitudinal axis and in that, to form the plate (P), the pressed-together roll (1′″) is cut along its longitudinal axis into disks (12).

10. The method as claimed in claim 9, characterized in that, for folding, the metal plate (1) is bent at regular intervals and in that the winding takes place in such a way that the roll (1″) has a star-shaped cross section.

11. The method as claimed in claim 9, characterized in that the roll (1″) is pressed into a rectangular, in particular square, cross-sectional form.

12. The method as claimed in claim 9, characterized in that the roll (1″) is pressed together in a direction perpendicular to the longitudinal axis to a density of from 70 to 90%.

13. The method as claimed in claim 9, characterized in that the disks (12) are pressed in a direction perpendicular to their disk plane.

14. A buffer element to reduce mechanical stresses between two materials with different coefficients of thermal expansion, characterized in that the buffer element is designed in the form of a plate and comprises a one-piece metal sheet having a pressed-together meandering form.

15. The buffer element as claimed in claim 14, characterized in that the metal sheet is folded together in a meandering manner in a direction perpendicular to a surface area of the buffer element.

16. The buffer element as claimed in claim 14, characterized in that the sheet is wound essentially in the form of a spiral extending in a surface area of the buffer element, the spiral having windings which extend in a meandering manner.
